(19) United States
(12) Patent Application Publication
(10) Pub. No.: US 2020/0082877 A1
(43) Pub. Date: Mar. 12, 2020

(54) SEMICONDUCTOR MEMORY DEVICE

(71) Applicants: Kabushiki Kaisha Toshiba, Tokyo (JP); Toshiba Electronic Devices & Storage Corporation, Tokyo (JP)

(72) Inventor: Tsuyoshi Midorikawa, Yokohama Kanagawa (JP)

(21) Appl. No.: 16/298,507

(22) Filed: Mar. 11, 2019

(30) Foreign Application Priority Data
Sep. 12, 2018 (JP) 2018-170381

(51) Int. Cl. G11C 11/419; G11C 11/412; G11C 11/418

(52) U.S. Cl. CPC G11C 11/419; G11C 11/418; G11C 11/412

(57) ABSTRACT

According to one embodiment, there is provided a semiconductor memory device including a memory cell provided with a pair of storage nodes that complementarily store data, a pair of bit lines that are complementarily driven based on data to be written in the memory cell, a word line that performs row selection of the memory cell, a word line driver that drives the word line, a first switch that is able to control connection and disconnection of power supply of the word line driver, wherein a node that connects the word line driver and the first switch is shared with another word line driver.

### CROSS-REFERENCE TO RELATED APPLICATIONS

This application is based upon and claims the benefit of priority from Japanese Patent Application No. 2018-170381, filed Sep. 12, 2018, the entire contents of which are incorporated herein by reference.

### FIELD

Embodiments described herein relate generally to a semiconductor memory device.

### BACKGROUND

In a semiconductor memory device including a plurality of static random access memory (SRAM) cells, a problem that the stored data is inverted due to a disturbance failure may occur depending on a variation in the threshold voltage Vth of individual transistors constituting the cell at the time of reading stored data.

In order to avoid such a situation, many techniques have been proposed in which the operating voltage level of the word line at the time of reading is dynamically changed (decreased) as compared with the operating voltage level at the time of subsequent writing operation.

As a specific technique for temporarily lowering the operating voltage of the word line at the time of reading, there are a method of switching two power sources having different power supply voltages, a method of adding a circuit for controlling connection and disconnection of a branch path in which a through-current is generated so as to change the ratio of the DC level, a method of controlling the switching of two paths having the same power supply voltage but having different current values, and the like.

### BRIEF DESCRIPTION OF THE DRAWINGS

FIG. 1 is a schematic diagram showing an extracted part of the configuration of a semiconductor memory device according to an embodiment;

FIG. 2 is a diagram illustrating a circuit configuration of a switch and a word line driver according to the embodiment;

FIG. 3 is a diagram illustrating operation signal waveforms in respective parts of FIG. 2;

FIG. 4 is a diagram illustrating a configuration of a memory cell and operation waveforms at the time of reading according to the embodiment; and

FIG. 5 is a diagram showing a configuration in the case where nodes “a0” to “an” are all shared in correspondence with all the word lines according to the embodiment with connection switches omitted.

### DETAILED DESCRIPTION

Hereinafter, embodiments will be described with reference to the accompanying drawings.

In general, according to one embodiment, there is provided a semiconductor memory device including a memory cell provided with a pair of storage nodes that complementarily store data, a pair of bit lines that are complementarily driven based on data to be written in the memory cell, a word line that performs row selection of the memory cell, a word line driver that drives the word line, a first switch that is able to control connection and disconnection of power supply of the word line driver, wherein a node that connects the word line driver and the first switch is shared with another word line driver.

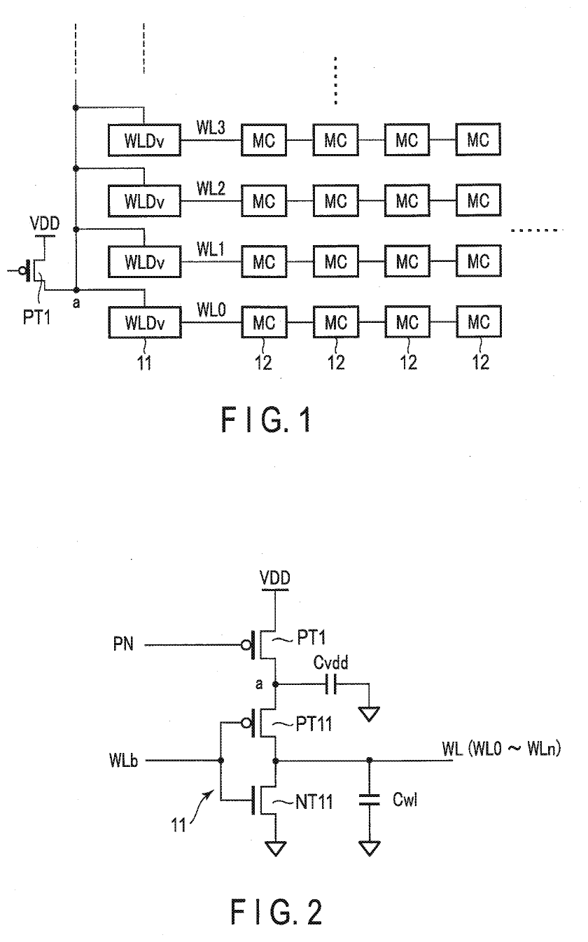

FIG. 1 is a schematic diagram showing an extracted part of the configuration of a semiconductor memory device according to an embodiment. In the figure, word lines WL0, WL1, . . . . are connected in the row direction to an array of memory cells (MC) 12, . . . . arranged in a matrix, and word line drivers (WLDv) 11, . . . are arranged at one ends of the respective word lines WL0, WL1, . . . .

Though each of the memory cells 12, . . . includes a plurality of transistors, a plurality of transistors are collectively represented by one block in FIG. 1. Although the number of the plurality of transistors is assumed to be six, for example, the number is not limited thereto, and may be eight or another, for example.

In addition, in FIG. 1, in order to avoid complicated description, illustrations of a plurality of bit line pairs connecting the memory cells 12, . . . in the column direction, a bit-line-pair selector provided at one end of each bit line pair or the like is omitted.

To each of the word line drivers 11, . . . , a transistor (first switch) PT1 formed of a P-channel metal-oxide-semiconductor field-effect transistor (MOSFET) for example is provided as a switch for controlling the connection and disconnection of a power supply voltage VDD of the word line driver. FIG. 1 shows mainly the configuration relating to the lowermost word line WL0 and some of the word lines adjacent thereto, and the configurations relating to word lines other than these word lines are omitted. As shown in the figure, a node a connected to the transistor PT1 is configured such that the plurality of adjacent word line drivers 11, . . . are connected to the node a to share this node.

FIG. 2 is a diagram illustrating a circuit configuration including the word line driver 11 provided on each word line and the transistor PT1 as a switch. The word line driver 11 forms a complementary type circuit with a transistor PT11 made of a P-channel MOSFET and a transistor NT11 made of an N-channel MOSFET, and the drain of the transistor PT1 is connected to the source of the transistor PT11 via the node a. The power supply voltage VDD is applied to the source of the transistor PT1, and a power supply control signal PN is supplied to the gate of the transistor PT1.

A control signal WLb for a word line is input to each gate of the transistor PT11 and the transistor NT11 constituting the word line driver 11, and its inverted output is supplied to the word line WL (WL0, WL1, . . . ) of the memory cell 12 in the subsequent stage.

The node a connected to the transistor PT1 is configured to be connected to the plurality of adjacent word line drivers 11, . . . to be shared by the drivers, as described above. The number of the word line drivers connected to the node a to share this node or the number (unit number) of the corresponding word lines is determined according to the ratio of a capacitance Cvdd on the source side of the transistor PT11 at the node a to a capacitance Cwl on the output side of the word line WL. It should be noted that another transistor PT1 (not shown) and another node connected thereto may be present. The configuration in that case is the same as above.

As an example, the case is cited where when the number of the memory cells 12, . . . connected to one word line WL is 256, adjacent 32 rows of lines are connected as one unit to the node a so as to set up the capacitance Cvdd with respect to the capacitance Cwl of the word line WL.

Next, the operation in the above configuration will be described.

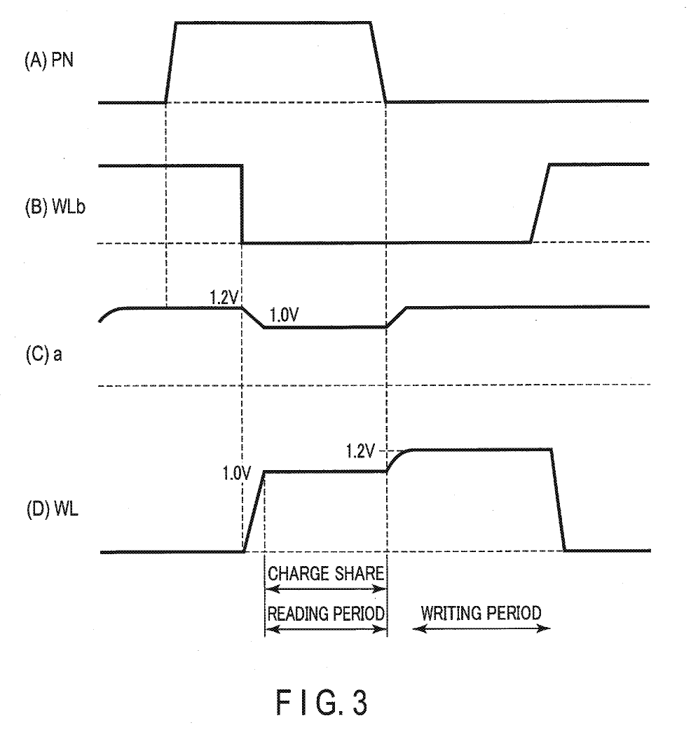

FIG. 3 is a diagram illustrating operation signal waveforms in each part of the configuration of FIG. 2.

In FIG. 3, (A) shows the power supply control signal PN supplied to the gate of the transistor PT1 serving as a switch. The power supply control signal PN shifts from a low level to a high level at a predetermined time before the reading and writing of the word line WL and drops to a low level in accordance with the timing at which the writing period starts after the reading period ends.

In FIG. 3, (B) shows the control signal WLb which is at a low level as the input to the word line driver 11 during the period of reading and writing of the word line WL.

As a result, the node a of the word line driver 11 and the transistor PT11 of the word line driver 11 maintains the power supply voltage VDD, for example, 1.2 m during a period before the reading period as shown in (C) of FIG. 3.

Thereafter, in a process in which the control signal WLb drops to a low level and the potential of the word line WL which is the inverted output of the word line driver 11 rises, the potential drops from the original power supply voltage VDD, namely 1.2 [V] for example by a certain value 0.2 [V] for example due to the charge sharing corresponding to the ratio of the capacitance Cvdd at the node a shared with the other adjacent word line drivers 11 to the capacitance Cwl of the word line WL.

Therefore, as shown in (C) and (D) of FIG. 3, a value of 1.0 [V] having dropped by a certain amount from the original voltage 1.2 [V], for example is maintained as the potential at the node a and the word line WL during the reading period.

After that, when the power supply control signal PN to the transistor PT1 drops to a low level at the time of starting the writing after the period of the reading ends, the state of the charge sharing ends and the potential at the node a and the word line WL rises to the original voltage 1.2 [V] for example. During this writing period, writing processing is executed in each of the memory cells 12, . . . connected to the word line WL.

When the writing period ends, the control signal WLb rises to a high level, and the potential of the word line WL which is the inverted output of the word line driver 11 drops, and access to the memory cells 12 connected to the word line WL is temporarily stopped until the next reading period.

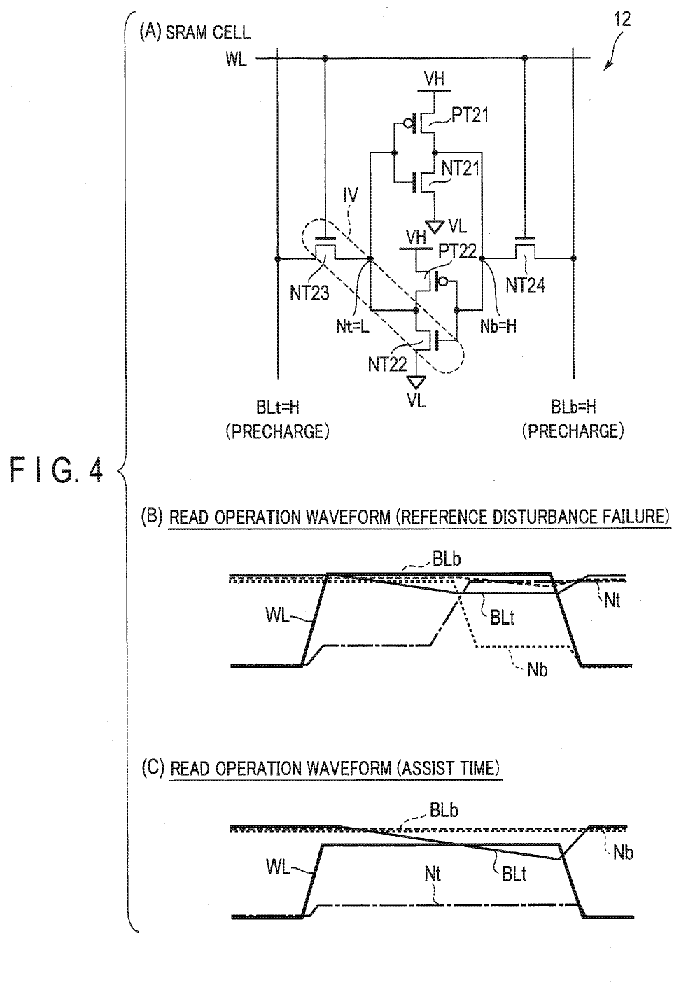

FIG. 4 is a diagram showing configuration and the operation of one of the memory cells 12, . . . connected to the word line WL controlled so as to have the potential described above.

In FIG. 4, (A) shows an example of the configuration of the memory cell 12, in which the memory cell 12 is formed of a CMOS type memory cell with six transistors. The memory cell 12 includes transistors PT21 and PT22 which are P-channel MOSFETs and transistors NT21 to NT24 which are N-channel MOSFETs.

The transistor PT21 is connected between a high-side power supply node VH and a storage node Nb, and further the gate thereof is connected to a storage node Nt. The transistor NT21 is connected between the storage node Nb and a low-side power supply node VL, and its gate is connected to the storage node Nt.

The transistor PT22 is connected between the high-side power supply node VH and the storage node Nt, and its gate is connected to the storage node Nb. The transistor NT22 is connected between the storage node Nt and the low-side power supply node VL, and its gate is connected to the storage node Nb.

The transistor NT23 connects the storage node Nt to a bit line BLt according to the voltage on the word line WL. The transistor NT24 connects the storage node Nb to a bit line BLb according to the voltage on the word line WL.

In FIG. 4, (A) shows a state in which both the bit lines BLt and BLb are precharged to a high (H) potential level, and the storage node Nt is held at a low (L) level, and further the storage node Nb is held at the high (H) level as an example.

In the configuration of the SRAM memory cell 12 as described above, tolerance to the disturbance is determined particularly by the capability ratio of the transistors NT22 and NT23 constituted by the two N-channel MOSFETs in the range indicated by broken line IV in the figure.

In FIG. 4, (B) shows an example of the operation waveform of the case where the operation is performed without executing the assist control for lowering the potential of the word line WL at the time of reading from the specified power supply voltage as in the present embodiment for reference. Since the potential of the word line WL and the potential of the bit lines BLt and BLb are about the same at the beginning of the reading period, when a disturbance failure occurs, the potential of the storage node Nt is pulled up to a level higher than the assumed level, and the potential of the storage node Nb is pulled down to the low level by the transistor NT21 receiving the influence, and consequently the stored (held) content is inverted.

In FIG. 4, (C) shows an example of operation waveforms in the case where the operation is executed with the assist control for lowering the potential of the word line WL at the time of reading from the specified power supply voltage in the present embodiment. During the reading period, the potential of the word line WL is controlled to be clearly lower than the potentials of the bit lines BLt and BLb.

Therefore, even when resistance to disturbance failure is low due to individual differences of transistors or the like, the storage node at a low level potential at that time, namely the storage node Nt in this case is not pulled up to a high level and also the storage node Nb at a high level potential conversely is not pulled down to a low level so that the stored contents are correctly held.

In the above-described embodiment, although description has been given assuming that the node a between the transistor PT1 and the word line driver 11 is connected to the adjacent word line drivers 11, . . . to be shared by a predetermined number of units, the number of units of the word line drivers 11 to be connected for sharing may be variable to be freely set by a second switch (not shown) without being fixed. For example, a plurality of circuits each may be configured to have the same configuration as the circuit connecting the transistor PT1 and the word line driver 11 via the node a, and the above-mentioned second switch can connect and disconnect a part of the connection line connecting respective nodes. Further, the adjacent nodes a may be connected to each other via the above-mentioned second switch, which can connect and disconnect between any nodes a.

By making it possible to freely set the connection state between the nodes a in this manner, the ratio of the capacitance of the node a connecting the transistor PT1 and the word line driver to the capacitance of the word line WL can be adjusted depending on the operation state of the semiconductor memory device.

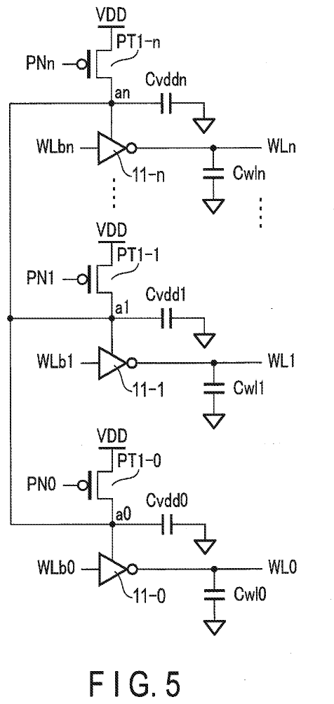

FIG. 5 is a diagram showing the configuration in which nodes a0 to an connecting transistors PT1-0 to PT1-n to word line drivers 11-0 to 11-n, respectively, are all connected and made into a shared state corresponding to all word lines WL0 to WLn provided in the semiconductor memory device, omitting the above-mentioned second switch to be connected.

In this manner, by connecting all the nodes a0 to an to secure a shared state, operation can be carried out with the assist control of lowering the potential of the word line WL maximally from the specified power supply voltage at the time of reading.

According to the embodiments as described in detail above, it is possible to provide a semiconductor memory device capable of implementing an assist operation for temporarily lowering the power supply voltage of the word line without wastefully consuming electric power at the time of reading from a memory cell.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made. The accompanying claims and their equivalents are intended to cover such forms or modifications as would fall within the scope of the inventions.

1. A semiconductor memory device comprising:
a memory cell provided with a pair of storage nodes that complementarily store data;
a pair of bit lines that are complementarily driven based on data to be written in the memory cell;
a word line that performs row selection of the memory cell;
a word line driver that drives the word line; and
a first switch that is able to control connection and disconnection of power supply of the word line driver, wherein
a node that connects the word line driver and the first switch is shared with another word line driver.

2. The semiconductor memory device according to claim 1, wherein
a number of word line drivers that share the node is determined according to a ratio of a capacitance of the node to a capacitance of the word line.

3. The semiconductor memory device according to claim 1, further comprising
a second switch that variably sets a ratio of a capacitance of the node to a capacitance of the word line.

4. The semiconductor memory device according to claim 3, wherein
a plurality of circuits that have the same configuration as a circuit that connects the first switch and the word line driver via the node are present, and
the second switch is configured to be able to connect and disconnect at least a part of a connection line that connects each node.

5. The semiconductor memory device according to claim 1, wherein
a potential of the word line during a reading period is maintained to be lower than the potential of the word line during a writing period.

6. The semiconductor memory device according to claim 1, wherein
the first switch is constituted by a metal-oxide-semiconductor field-effect transistor (MOSFET).
